(19) United States
(12) Patent Application Publication
(10) Pub. No.: US 2012/0109546 A1
(43) Pub. Date: May 3, 2012

(54) IDENTIFICATION OF ROTOR BROKEN BAR IN PRESENCE OF LOAD PULSATION

(75) Inventors: Arvind Kumar Tiwari, Bangalore (IN); Arijit Banerjee, Bangalore (IN); Jeffrey Glenn Mazereeuw, Newmarket (CA)

(73) Assignee: GENERAL ELECTRIC COMPANY, SCHENECTADY, NY (US)

(21) Appl. No.: 12/916,166

(22) Filed: Oct. 29, 2010

(51) Int. Cl. G01R 31/34; H02H 7/08

(52) U.S. Cl. 702/58; 361/30

(57) ABSTRACT

A method for detecting an anomaly in a rotor of an induction machine is provided. The method includes obtaining or receiving three-phase stator voltage and current signals from the induction machine connected to a time varying load. The method also includes processing the three-phase stator voltage and current signals by transforming into corresponding two-phase quantities. Further, the method includes transforming the two-phase quantities into two quadrature components into a two-phase reference frame. The method includes analyzing a plurality of in-phase components and the quadrature components. Finally, the method includes detecting the presence of an anomaly and segregating the anomaly from load variations based on the analysis of the plurality of in phase components and the quadrature components, thereby reducing false alarm.

### BACKGROUND

The invention relates generally to detecting anomalies in a rotor of induction machines and more particularly to a method and system of detecting an anomaly in the rotor of the induction machine in presence of load pulsations.

Induction machines such as motors or generators are used in a wide array of applications and processes. Generally, the induction machines are recognized with problems or anomalies during the operation. Non-limiting examples of such anomalies includes broken rotor bar(s), failure in an end ring, etc. in the rotor. Especially, a rotor anomaly is one of the predominant failure modes of the induction machines. Rotors are typically manufactured either from aluminum alloy, copper or copper alloy or copper windings. Large machines generally have rotors and end-rings fabricated out of these materials, whereas motors with ratings less than a few hundred horsepower generally have die-cast aluminum alloy rotor cages. Some induction machines also use copper windings and slip ring and brush arrangements. Such rotor anomalies arise as a result of material and structural flaws introduced during manufacturing, overheating during operation or periods of extended service of the machine causing fatigue failures. These defects can result in multiple secondary deterioration ranging from sparking in a hazardous area, rotor core damage due to overheating, premature wearing of the bearings and driven components, non-uniform bar expansion causing imbalance and subsequent bearing failures and eventually catastrophic induction machine failures during high speed rotation of broken bars. Furthermore, a degraded rotor of the machine may also not able to develop sufficient accelerating torque. Replacement of the rotor core in larger machine is costly and time consuming; therefore, by detecting anomaly in advance, such secondary deterioration can be prevented. Currently detection of anomalies is solved using frequency spectrum of input current to determine the rotor broken bar failures and bearing failures of the induction machine in a steady load condition. However, such anomaly detection methods have limitations for applying to induction machines that drive a pulsating load such as a reciprocating compressor, pump and other mechanical systems.

Accordingly, there is an ongoing need for improving upon accurately detecting rotor anomalies, or the onset of rotor anomalies in presence of load pulsations.

### BRIEF DESCRIPTION

In accordance with an embodiment of the invention, a method for detecting an anomaly in a rotor of an induction machine is provided. The method includes obtaining or receiving three-phase stator voltage and current signals from the induction machine connected to a time varying load. The method also includes processing the three-phase stator voltage and current signals by transforming into corresponding two-phase quantities. Further, the method includes transforming the two-phase quantities into two quadrature components into a two-phase reference frame. The method includes analyzing a plurality of in-phase components and the quadrature components. Finally, the method includes detecting the presence of an anomaly and segregating the anomaly from load variations based on the analysis of the plurality of in phase components and the quadrature components.

In accordance with an embodiment of the invention, a system for determining an anomaly in a rotor of an induction machine is provided. The system includes a device module in communication to the induction machine and configured to measure characteristics of the machine. Further, the device includes a memory, wherein the memory comprises instructions for obtaining or receiving three-phase stator voltage and current signal from the induction machine connected to a time varying load, processing the three-phase stator voltage and current signals by transforming into a corresponding two-phase quantities, transforming the two-phase quantities into two quadrature components into a two phase reference frame, analyzing a plurality of in-phase components and the quadrature components and detecting the presence of an anomaly and segregating the anomaly from load variations based on the analysis of the plurality of in phase components and the quadrature components.

### DRAWINGS

These and other features, aspects, and advantages of the present invention will become better understood when the following detailed description is read with reference to the accompanying drawings in which like characters represent like parts throughout the drawings, wherein:

FIG. 1 is a block diagram of a system for determining an anomaly in a rotor of an induction machine in accordance with an embodiment of the present invention.

FIG. 2 shows the per phase equivalent circuit of the induction machine of the system as shown in FIG. 1.

FIG. 3 is a graphical representation of stator windings and rotor windings illustrating a schematic of transformation of currents from 3-phase rotational reference frame to a two-axis reference frame.

FIG. 4 shows a plot of computation results of a torque component I_{sq} current signature under a time varying load for a healthy induction machine carried out by the system as shown in FIG. 1.

FIG. 5 shows a plot of computation results of a torque component I_{sq} current signature under a time varying load for an induction machine having a broken rotor bar fault.

FIG. 6 illustrates a plot of computation results of a flux component I_{sd} current signature under a time varying load for an induction machine having a broken rotor bar fault.

FIG. 7 shows a flow chart of a method for detecting an anomaly in a rotor of an induction machine in accordance with an embodiment of the invention.

### DETAILED DESCRIPTION

When introducing elements of various embodiments of the present invention, the articles “a,” “an,” “the,” and “said” are intended to mean that there are one or more of the elements. The terms “comprising,” “including,” and “having” are intended to be inclusive and mean that there may be additional elements other than the listed elements. Further, the term ‘processing’ may refer to reading or recording or rewriting or retrieving of data from a holographic data storage system. Any examples of operating parameters are not exclusive of other parameters of the disclosed embodiments.

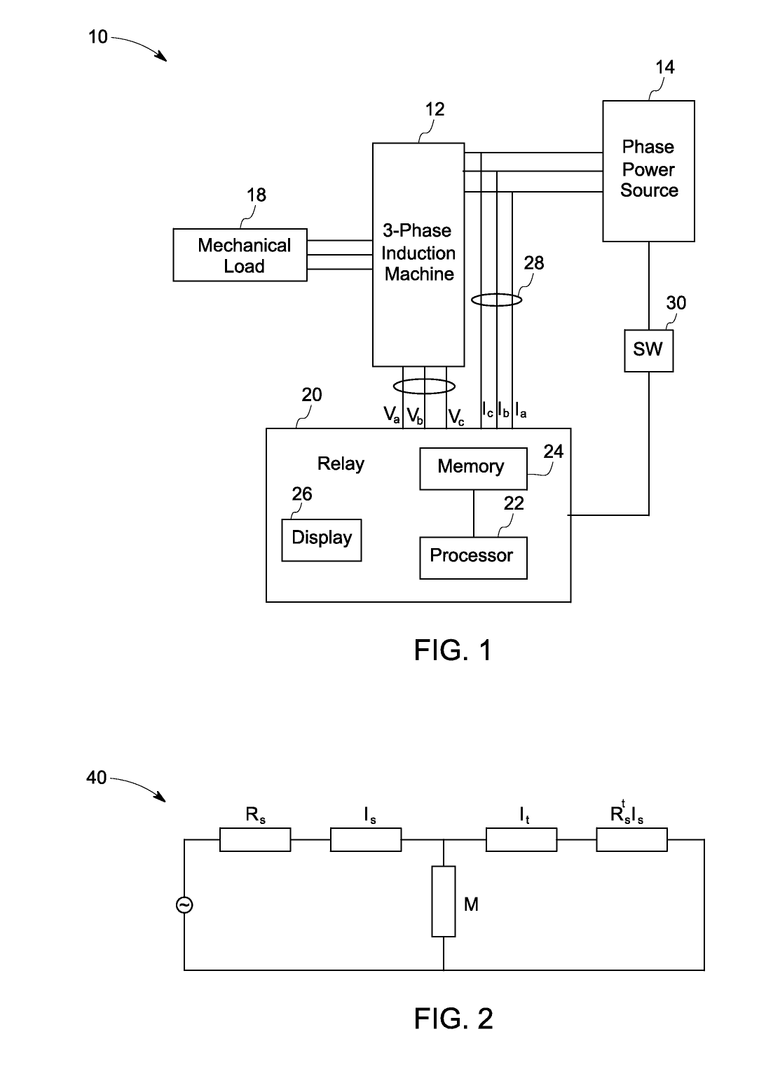

FIG. 1 is a block diagram of a system 10 that includes the induction for determining an anomaly in a rotor of an induction machine 12 in accordance with an embodiment of the present invention. The system 10 includes a three-phase induction machine 12 coupled to a three-phase power source 14, such as an AC mains or other source of AC power. Generally, the induction machine 12 includes rotor assembly (not shown) having a plurality of rotor bars extending along the outside. The rotor assembly along with the shaft can rotate inside the stator assembly in a clockwise or a counter-clockwise direction. Bearing assemblies that surround the rotor shaft may facilitate such rotation within the stator assembly. The stator assembly includes a plurality of stator windings that extend circumferentially around and axially along the rotor shaft through the stator assembly. During operation, a rotating magnetic field is produced by the currents flowing in the stator windings reacts with the induced current in the rotor assembly to cause the rotor assembly to rotate, converting electrical energy to mechanical energy output through the shaft.

The three-phase AC power is delivered to the induction motor 10, as indicated by a plurality of lines. The induction machine 12 is connected to a DC generator and further connected to a mechanical load 18. The mechanical load 18 is a time varying load that may be cyclic or pulsating load such as a reciprocating load, crusher load or load connected through gears, belt-pulley mechanisms and a plurality of mechanical arrangements. Also the time varying load may be a cyclic or pulsating load including a load due to a generator connected to the induction machine 12. ‘To control and monitor the induction machine 12, a device module 20, such as a relay, meter, or any other suitable device, is coupled to the induction machine 12. It should be appreciated that the device 20 may include components of, or may be, a computer. For example, as depicted, the device module 20 includes a processor 22, a memory 24 and a display 26. The display 27 includes visual and/or audio display capability. The memory 24 includes any suitable volatile memory, non-volatile memory, or combination thereof. The memory 24 stores any parameters, algorithms, or other data for controlling and monitoring the induction machine 12 and further allows access to this data by the processor 24. It should be noted that embodiments of the invention are not limited to any particular processor for performing the processing tasks of the invention. The term “processor,” as that term is used herein, is intended to denote any machine capable of performing the calculations, or computations, necessary to perform the tasks of the invention. The term “processor” is intended to denote any machine that is capable of accepting a structured input and of processing the input in accordance with prescribed rules to produce an output. It should also be noted that the processor may be equipped with a combination of hardware and software for performing the tasks of the invention, as will be understood by those skilled in the art.

The device module 20 monitors various parameters of the induction machine 12. In a non-limiting example, the device module 20 is coupled to various monitoring components, such as sensors, transformers, etc., in the induction machine 12. The monitoring components functions to monitor current, voltage, or any other parameter. As indicated by lines 28, the device module 20 receives induction machine phase current from the three-phase induction machine 12 connected to a time varying load. According to one embodiment, the time varying load is a cyclic or pulsating load including a crusher load, a reciprocating load or load connected through gears, belt-pulley mechanisms and a plurality of mechanical arrangements. According to another embodiment, the time varying load is a cyclic or pulsating load including a load due to a generator connected to the induction machine. Additionally, the device 20 receives induction machine phase voltage from the three-phase induction machine 12 connected to the mechanical load 18. It should be appreciated that various signal processing components may be included in the device module 20 or between the induction machine 12 and the device module 20, such as signal conditioners, amplifiers, filters, etc. The device module 20 also includes a switch 30 to turn the induction machine 12 on and off. As explained further below, the device module 20 may shutdown the induction machine 12 via the switch 30 in response to a rotor anomaly.

Furthermore, the memory 24 of the device module 20 includes a plurality of instructions or algorithm for determining the anomaly in the rotor of the induction machine 12. In one embodiment, the instructions in the memory 24 include obtaining or receiving three-phase stator current signals 28 (Iₐ, I_{b}, and I_{c}) and voltages 30 (Vₐ, V_{b}, and V_{c}) from the induction machine 12 connected to a time varying load (power source 14 connected to the programmable bank 18). In another embodiment, the instructions include processing the three-phase stator current signals 28 and voltages 30 by transforming into corresponding two-phase quantities by using a conversion matrix in a stator reference frame or a rotor reference frame or a arbitrary reference frame, wherein the two-phase quantities includes a stator current vector quantity, Īₛ and a voltage vector quantity, V̅ₛ, given by the following equations:

V̅=Vₐ+1 [symbol] 120°V_{b}+1 [symbol] 240°V_{c} (1)

Īₛ=Iₐ+1 [symbol] 120°I_{b}+1 [symbol] 240°I_{c} (2)

Further, the processing includes computing a stator flux linkage ψ̅ₛ based upon the stator current vector quantity, Īₛ, a voltage vector quantity, V̅ₛ and resistance Rₛ of the stator of the induction machine 12 in the stator reference frame. The stator flux linkage ψ̅ₛ is given by the following equation:

ψ̅ₛ=∫( V̅ₛ−RₛĪₛ)dt (3)

Furthermore, the stator flux linkage ψ̅ₛ in the stator reference frame is transformed into a rotor flux linkage ψ̅ᵣ using known machine parameters and the stator current vector quantity, Īₛ. The rotor flux linkage ψ̅ᵣ is given by the following equation:

$${\overline{ψ}}_{r} = \frac{{L}_{r}}{M} [ Re ( {\overline{ψ}}_{s} ) - σ {L}_{s} Re ( {\overline{I}}_{s} ) ] + j \frac{{L}_{r}}{M} [ Im ( {\overline{ψ}}_{s} ) - σ {L}_{s} Im ( {\overline{I}}_{s} ) ] \qquad ( 4 )$$

wherein, Lᵣ is the inductance of the rotor of the induction machine 12, M is the mutual inductance, Lₛ the inductance of the stator of the induction machine 12, and σ is a quantity given by

$$σ = 1 - \frac{{M}^{2}}{{L}_{s} {L}_{r}} \qquad ( 5 )$$

According to one embodiment FIG. 2 shows the per phase equivalent circuit of the induction machine 12 of the system 10 as shown in FIG. 1. The known induction machine parameters lₛ and lᵣ are stator and rotor leakage inductances. The induction of the rotor, Lᵣ is typically a summation of the mutual inductance M and the rotor leakage inductance lᵣ. Similarly, the induction of the stator is a summation of the mutual induction, M and the stator leakage induction lₛ.

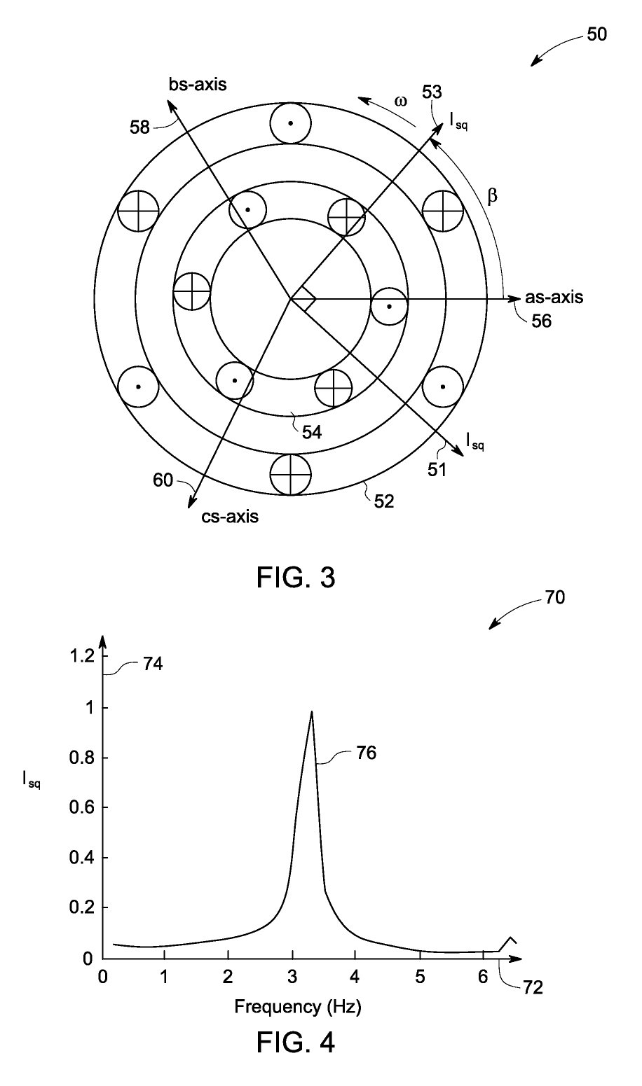

Further, the induction machines known parameters are used along with the rotor flux linkage ψ̅ᵣ to compute the rotor flux vector magnitude and phase. Furthermore, the rotor flux vector information is used to transform the stator current vector quantity, Īₛ into the rotor reference frame having two quadrature components namely a flux component I_{sd} and a torque component I_{sq} as shown in FIG. 3. It is to be noted that the reference frame may be a stator reference frame or a rotor reference frame or any arbitrary reference frame. The processing, thus, enables the transformation of the two-phase quantities (the stator current vector quantity, Īₛ and the voltage vector quantity, V̅ₛ) into two quadrature components into a two-phase reference frame. Further, the processing includes analysis of a plurality of in-phase components and the quadrature components and detecting the presence of an anomaly and finally segregating the anomaly from load variations based on the analysis of the plurality of in phase components and the quadrature components. According to the transformation used in this exemplified computation of d-axis and q-axis, the in phase components (d components) refer to flux axis component and quadrature component (q components) refers to torque axis component. The flux axis gets affected with the failure internal to machine, like broken bar, while both the axes get affected because of load pulsation. This not only helps to minimize the unscheduled down time of the machine by monitoring rotor bars' health and alarming prior to a catastrophic failure but also reduces false alarm due to load condition.

FIG. 3 is a graphical representation 50 of stator windings 52 and rotor windings 54 illustrating a schematic of transformation of currents from 3-phase stationary reference frame to a two-axis reference frame, which either can be stationary relative to the stator windings or can be rotating at an arbitrary frequency 52. As shown, in the two-axis reference the direct axis (d-axis represented by 51) to the quadrature axis (q-axis represented by 53) is offset by 90 degrees. As illustrated in this non-limiting example for segregating internal fault to external pulsation, the two-axis reference frame is attached to the rotor flux i.e it is rotating with d-axis aligned to rotor flux axis. FIG. 3 also shows the orientation of the axes as, bs and cs represented by 56, 58 and 60 respectively for the stator current signals 28 (Iₐ, I_{b}, and I_{c}) shown in FIG. 1. As illustrated, the quadrature components namely the flux component I_{sd} and the torque component I_{sq} are the sum of the projections of the stator current signals 28 (Iₐ, I_{b}, and I_{c}) shown in FIG. 1. Both the flux component I_{sd} and the torque component I_{sq} are thus, orthogonal components. According to one embodiment, the flux component I_{sd} is predominantly affected by the anomaly of the induction machine connected to a time varying load or a steady load as compared to the torque component I_{sq}.

By way of non-limiting examples, FIG. 4 shows a plot 70 of computation results of a torque component I_{sq} current signature under a time varying load for a healthy induction machine carried out by the system as shown in FIG. 1. It is to be noted that the computation results are mathematical analysis of the quadrature components based on frequency or time. The X-axis represented by 72 depicts frequency in hertz (units). The Y-axis represented by 74 depicts the torque component I_{sq} current signature expressed in ampere units. The peak 76 shows the pulsating load.

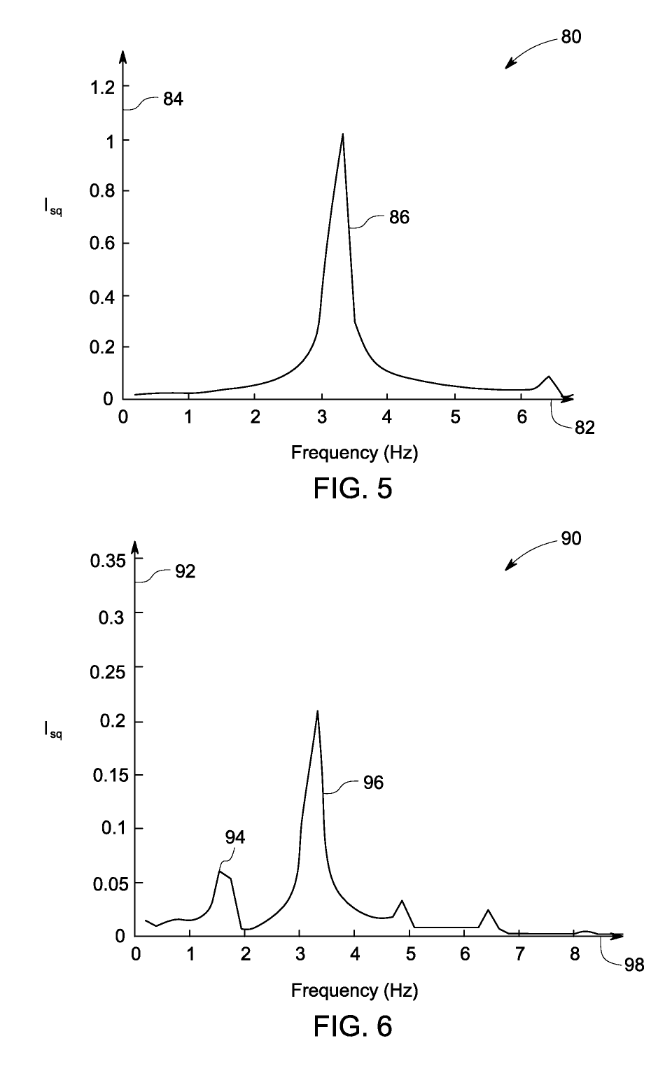

Similarly, FIG. 5 shows a plot 80 of computation results of a torque component I_{sq} current signature under a time varying load for an induction machine having a broken rotor bar. The X-axis represented by 82 depicts frequency in hertz (units). The Y-axis represented by 84 depicts the torque component I_{sq} current signature expressed in ampere units. The peak 86 reflects the pulsating load but does not capture the effect from the anomaly (broken bar) associated with the induction machine. Whereas, FIG. 6 illustrates a plot 90 of computation results of a flux component I_{sd} current signature (Y-axis 92) under a time varying load for an induction machine having a broken rotor bar fault, clearly FIG. 6 shows the multiple peaks 94 and 96 depicting the anomaly in the induction machine. The X-axis represented by 98 depicts frequency in hertz (units). The peak 96 is similar to the peak captured for pulsating load in FIG. 4 and FIG. 5 for torque component I_{sq} current signature for healthy and broken bar induction machines as well as for flux component I_{sd} current signature under a time varying load for a healthy induction machine. The additional peak 94 represents the anomaly (broken bar fault) in the induction machine.

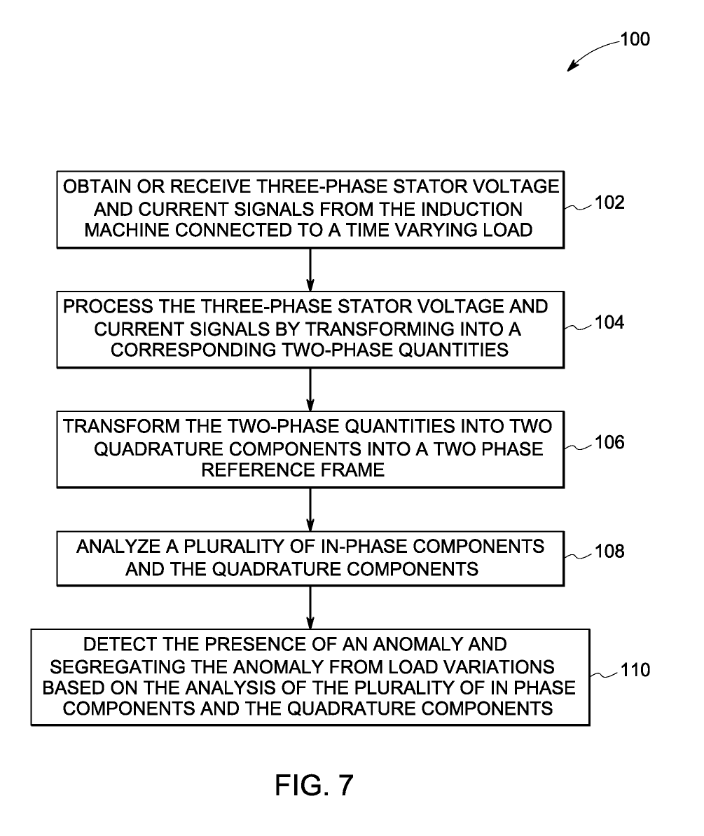

FIG. 7 shows a flow chart 100 of a method for detecting an anomaly in a rotor of an induction machine in accordance with an embodiment of the invention. At step 102, the method includes obtaining or receiving three-phase stator voltage and current signals from the induction machine connected to a time varying load. At step 102, the method includes processing the three-phase stator voltage and current signals by transforming into corresponding two-phase quantities. Further, at step 106 the method includes transforming the two-phase quantities into two quadrature components into a two-phase reference frame. The method also includes analyzing a plurality of in-phase components and the quadrature components at step 108. Finally, at step 110 the method includes detecting the presence of an anomaly and segregating the anomaly from load variations based on the analysis of the plurality of in phase components and the quadrature components.

Advantageously, the present method and system enables the processing of information from an induction machine for rapidly and easily detecting anomalies in a rotor of induction machines such as broken rotor bar(s), failure in an end ring, etc. Further, the above-mentioned algorithm, when employed with various computer(s) and/or machines, provides an on line monitoring capability of asset (e.g., induction machine) and allows the user to plan in advance the shutdown process and maintenance of machine with rotor side anomaly.

Furthermore, the skilled artisan will recognize the interchangeability of various features from different embodiments. Similarly, the various method steps and features described, as well as other known equivalents for each such methods and feature, can be mixed and matched by one of ordinary skill in this art to construct additional systems and techniques in accordance with principles of this disclosure. Of course, it is to be understood that not necessarily all such objects or advantages described above may be achieved in accordance with any particular embodiment. Thus, for example, those skilled in the art will recognize that the systems and techniques described herein may be embodied or carried out in a manner that achieves or optimizes one advantage or group of advantages as taught herein without necessarily achieving other objects or advantages as may be taught or suggested herein.

While only certain features of the invention have been illustrated and described herein, many modifications and changes will occur to those skilled in the art. It is, therefore, to be understood that the appended claims are intended to cover all such modifications and changes as fall within the true spirit of the invention.

What is claimed is:

1. A method of detecting an anomaly in a rotor of an induction machine, the method comprising:
obtaining or receiving three-phase stator voltage and current signals from the induction machine connected to a time varying load;
processing the three-phase stator voltage and current signals by transforming into a corresponding two-phase quantities;
transforming the two-phase quantities into two quadrature components into a two phase reference frame;
analyzing a plurality of in-phase components and the quadrature components; and
detecting the presence of an anomaly and segregating the anomaly from load variations based on the analysis of the plurality of in phase components and the quadrature components.

2. The method of claim 1, wherein the reference frame is a stator reference frame or a rotor reference frame or any arbitrary reference frame.

3. The method of claim 1, wherein the time varying load is a cyclic or pulsating load comprising a crusher load.

4. The method of claim 3, wherein the time varying load is a cyclic or pulsating load comprising a reciprocating load or load connected through gears, belt-pulley mechanisms and a plurality of mechanical arrangements.

5. The method of claim 3, wherein the time varying load is a cyclic or pulsating load comprising a load due to a generator connected to the induction machine.

6. The method of claim 1, wherein the processing of three-phase stator current signal into the two-phase current signal is carried out using a conversion matrix in a stator reference frame or a rotor reference frame or a arbitrary reference frame.

7. The method of claim 1, further comprising measuring a plurality of voltage signals and a plurality of machine parameters from the induction machine.

8. The method of claim 6, wherein the plurality of machine parameters include stator resistance, mutual inductance and leakage inductances.

9. The method of claim 1, further comprising estimating a stator and rotor flux vector magnitude and a stator and rotor flux vector phase using the measured plurality of voltage and current signals and the plurality of machine parameters.

10. The method of claim 1, further comprising transforming the two-phase current signal in a stator reference frame or a rotor reference frame or any arbitrary reference frame into two quadrature components in the corresponding reference frame using the estimated stator and rotor flux vector magnitude and the stator and rotor flux vector phase.

11. The method of claim 1, wherein the quadrature components are orthogonal components having a torque component and a flux component.

12. The method of claim 1, wherein the analyzing comprises a mathematical analysis of the quadrature components based on frequency or time, wherein the flux component includes both the time varying load signature and the anomaly of the rotor of the induction machine.

13. The method of claim 1, wherein the analyzing comprises a mathematical analysis of the quadrature components based on frequency or time, wherein the torque component includes the time varying load signature.

14. A system for determining an anomaly in a rotor of an induction machine, comprising:
a device module in communication to the induction machine and configured to measure characteristics of the machine, the device module comprising a memory, wherein the memory comprises instructions for:
obtaining or receiving three-phase stator voltage and current signal from the induction machine connected to a time varying load;
processing the three-phase stator voltage and current signals by transforming into a corresponding two-phase quantities;
transforming the two-phase quantities into two quadrature components into a two phase reference frame;
analyzing a plurality of in-phase components and the quadrature components; and
detecting the presence of an anomaly and segregating the anomaly from load variations based on the analysis of the plurality of in phase components and the quadrature components.

15. The system of claim 14, wherein the reference frame is a stator reference frame or a rotor reference frame or any arbitrary reference frame.

16. The system of claim 14, wherein the device module comprises a processor and a display device coupled to the processor to output the presence of anomaly in the rotor of the induction machine.
